(19) United States
(12) Patent Application Publication
(10) Pub. No.: US 2013/0258565 A1
(43) Pub. Date: Oct. 3, 2013

(54) DISPLAY UNIT AND ELECTRONIC APPARATUS

(71) Applicant: SONY CORPORATION, Tokyo (JP)

(72) Inventor: Shota Nishi, Kanagawa (JP)

(73) Assignee: Sony Corporation, Tokyo (JP)

(21) Appl. No.: 13/777,837

(22) Filed: Feb. 26, 2013

(30) Foreign Application Priority Data
Mar. 30, 2012 (JP) 2012-080641

(51) Int. Cl. H05K 7/14

(52) U.S. Cl. CPC H05K 7/14
USPC 361/679.01

(57) ABSTRACT

There are provided a display unit and an electronic apparatus that allow the visibility to be enhanced without deteriorating the flexibility of the display unit. The display unit includes: a display member having flexibility; and a support member disposed at a back side of the display member and having a shape-memory functionality.

### BACKGROUND

The present disclosure relates to a display unit having flexibility, and an electronic apparatus.

In recent years, a low-profile display unit called electronic paper has been utilized as a book (so-called electronic book). Such a low-profile display unit has the flexibility that allows a user to bend or twist it physically.

As an example of a display unit having the flexibility, a display unit has been proposed that has a laminated structure fabricated by, for example, attaching films to both sides of a display member (flexible panel) (for example, see Japanese Unexamined Patent Application Publication No. 2011-7904).

### SUMMARY

For a display unit as described above, however, there has been a disadvantage that the flatness of a display surface deteriorates contrary to the improved flexibility, causing the visibility to degrade. Further, there has been another disadvantage that the flexibility deteriorates in attempting to ensure the flatness of a display surface by a housing.

It is desirable to provide a display unit and an electronic apparatus that allow the visibility to be enhanced without deteriorating the flexibility of the display unit.

According to an embodiment of the present disclosure, there is provided a display unit includes: a display member having flexibility; and a support member disposed at a back side of the display member and having a shape-memory functionality.

According to an embodiment of the present disclosure, there is provided an electronic apparatus with a display unit. The display unit includes: a display member having flexibility; and a support member disposed at a back side of the display member and having a shape-memory functionality.

In the display unit and the electronic apparatus according to the above-described respective embodiments of the present disclosure, the support member having the shape-memory functionality is provided at the back side of the display member having the flexibility, which ensures the flatness of the display member while keeping the flexibility thereof.

In the display unit and the electronic apparatus according to the above-described respective embodiments of the present disclosure, a support member having a shape-memory functionality is provided at the back side of a display member having the flexibility, which ensures the flatness of the display member at a browsing time. Consequently, this makes it possible to enhance the visibility of a display surface at a browsing time without deteriorating the flexibility of the overall display unit.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present disclosure, and are incorporated in and constitute a part of this specification. The drawings illustrate embodiments and, together with the specification, serve to explain the principles of the present technology.

FIG. 1 is an exploded perspective diagram showing a configuration of a display unit according to an embodiment of the present disclosure.

FIG. 2 is a cross-sectional diagram of the display unit illustrated in FIG. 1.

FIG. 3A is a perspective diagram of the display unit illustrated in FIG. 1.

FIG. 3B is a perspective diagram showing a bending state of the display unit illustrated in FIG. 1.

FIG. 4A is a perspective diagram showing a state after bending of the display unit illustrated in FIG. 1.

FIG. 4B is a perspective diagram showing a state after heat supply to the display unit illustrated in FIG. 4A.

FIG. 5A is a perspective diagram showing an open state of an electronic apparatus (electronic book) according to an application example 1 of the present disclosure.

FIG. 5B is a perspective diagram showing a closed state (folded state) of the electronic book illustrated in FIG. 5A.

FIG. 6 is an exploded perspective diagram of the electronic book illustrated in FIGS. 5A and 5B.

FIG. 7 is a functional block diagram of the electronic book illustrated in FIGS. 5A and 5B.

FIG. 8A is a schematic diagram showing an example of user operation.

FIG. 8B is a schematic diagram showing another example of user operation.

FIG. 8C is a schematic diagram showing still another example of user operation.

### DETAILED DESCRIPTION

Hereinafter, some embodiments of the present disclosure are described in details with reference to the drawings. It is to be noted that the descriptions are provided in the order given below.

1. Embodiment (display unit: an example where sheet-like shape-memory alloy is attached at the back side of a display member)

### 1-1. Overall Configuration of Display Unit

### 1-2. Functionality of Display Unit

2. Application Example (electronic apparatus: electronic book)

### 1. Embodiment

### [1-1. Overall Configuration of Display Unit]

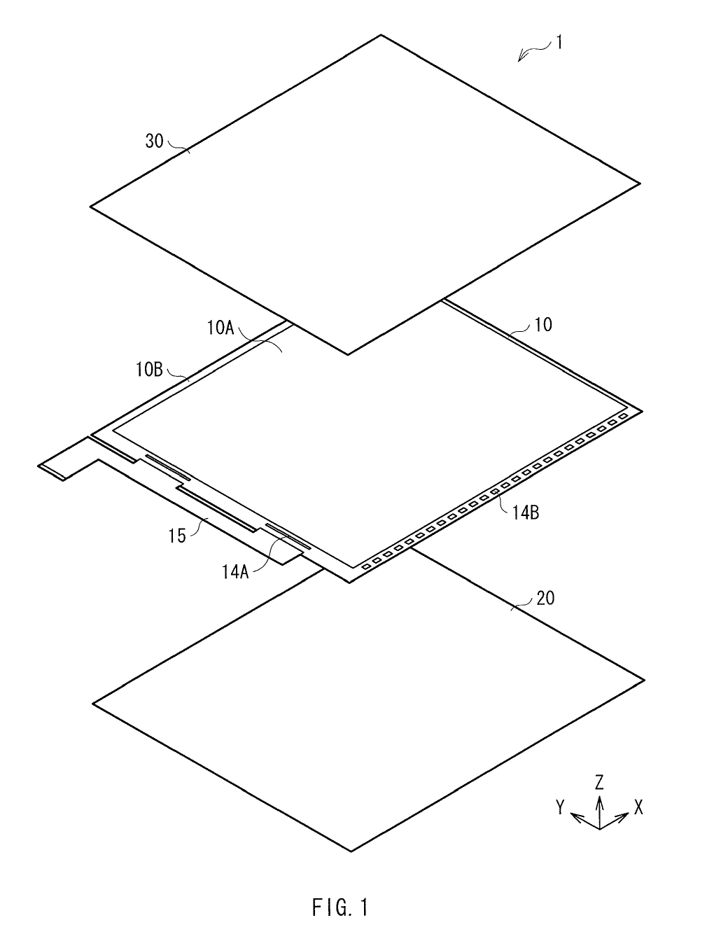

FIG. 1 shows a configuration of a display unit (display unit 1) according to an embodiment of the present disclosure as an exploded diagram. The display unit 1, which is used for a display section of an electronic book for example, includes a display member 10 having flexibility. In this embodiment of the present disclosure, the display unit 1 has a configuration in which a support member 20 having a shape-memory functionality is disposed at the back side of the display member 10, and an optical film 30 is attached at the front side of the display member 10.

In the present specification, in a principal surface (the widest surface) of the display member 10, a horizontal direction (long-side direction) is called X-direction, a vertical direction (short-side direction) is called Y-direction, and a thickness direction of the display member 10 is called Z-direction.

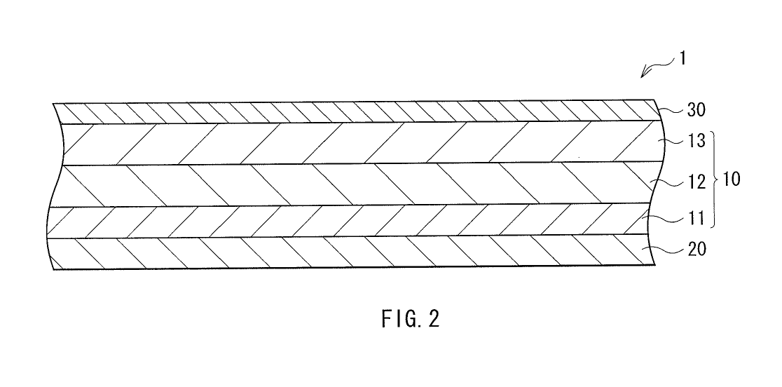

The display member 10 is a display panel that displays an image based on an image signal. As will hereinafter be described in detail, as shown in an example in FIG. 2, a semiconductor layer 12 and a display layer 13 are laminated in this order on a substrate 11 having the flexibility. Examples of a display device composing the display layer 13 include an organic Electroluminescence (EL) device, a liquid crystal display device, and an electrophoretic device.

As shown in FIG. 1, the display member 10 has a planar shape of a rectangle for example, where a rectangular display region 10A is provided at a substantially central position thereof. At a peripheral section 10B that is located outward from the display region 10A, for example, two oblong driver Integrated Circuits (ICs) 14A are mounted along a short side (Y-direction) of the display member 10 for example, and an Flexible Printed Circuit (FPC) 15 for signal input/output to/from external connection terminals is connected. Further, at the peripheral section 10B, for example, a plurality of driver ICs 14B are also mounted along a long side (X-direction) of the display member 10.

As described above, the display member 10 has a structure in which the semiconductor layer 12 and the display layer 13 are laminated on the substrate 11. Examples of a constituent material for the substrate 11 include a resin material, more specifically, a plastic material with a thickness of approximately 10 to 200 μm, such as polyethylene terephthalate, polyethylene naphthalate, polyether sulfone, polyether imide, polyether ether ketone, polyphenylene sulfide, polysulfone, polyarylate, polyimide, polyamide, polycarbonate, cellulose triacetate, polyolefin, polystyrene, polyethylene, polypropylene, polymethyl methacrylate, aramid, polyvinyl chloride, polyvinylidene chloride, epoxy resin, phenol resin, urea resin, melamine resin, silicon resin, or acrylic resin.

On the semiconductor layer 12, in concrete terms, there are provided a thin-film transistor (TFT) that is composed of, for example, a gate electrode, a gate insulating film, a semiconductor layer acting as a channel layer, and a source-drain electrode, and other elements (these are not shown in the figure). These are formed through deposition and etching processes using Chemical Vapor Deposition (CVD) method, and the like.

The display layer 13 has a liquid crystal layer, an organic EL layer, or an electrophoretic layer between a pixel electrode and a common electrode for example (these are not shown in the figure).

The support member 20 has a shape-memory functionality to support the display member 10. The support member 20 is composed of, for example, sheet-like (for example, film thickness of approximately 50 to 500 μm) shape-memory alloy, being disposed at the back side of the display member 10. Examples of shape-memory alloy types include various alloys such as nickel (Ni)-titanium (Ti), copper (Cu)-zinc (Zn)-aluminum (Al), gold (Au)-cadmium (Cd), indium (In)—Ti, Cu—Ni—Al, palladium (Pd)—Ti, Ni—Ti—Cu, Cu—Zn—Al—Ni, iron (Fe)-manganese (Mn)-silicon (Si), Au—Mn—Zn, Mn—Cu, and Cu—Al-beryllium (Be). It is to be noted that a constituent material for the support member 20 may have a shape-memory functionality as described above, and may include any material other than the shape-memory alloy alternatively. For example, a fluorocarbon resin such as polytetrafluoroethylene, as well as any other metallic, organic, or inorganic fiber, and the like may be included for a constituent material.

The support member 20 restores the display unit 1 to a preset shape by applying constant temperature thereto for example. In concrete terms, application of heat at a browsing time restores the flatness of the support member 20, while restoring the flatness of the display member 10 that is arranged at the support member 20. This improves the visibility of the display region 10A (display surface) on the display member 10. It is preferable that temperature (transformation point) for restoring the shape of the support member 20 be, for example, approximately 30 degrees centigrade or more and approximately 40 degrees centigrade or less in consideration of user safety.

As a source for supplying heat to the support member 20 at a browsing time, for example, a heater or the like may be provided as a dedicated heating means, although a heating element composing the display member 10 may be utilized for example as an alternative means. In concrete terms, for example, when a self-luminescent type organic EL device is selected as a display device composing the display layer 13, it is possible to make use of exhaust heat from the organic EL device itself. Apart from this, it is also possible to utilize exhaust heat from the TFT that is provided on the semiconductor layer 12, a Central Processing Unit (CPU (not shown in the figure)) that is provided at the peripheral section 10B, and the driver devices including the driver ICs 14A and 14B as well as the FPC 15. In such a manner, a thermal connection of the devices and the like, as a heat source, composing the display member 10 with the support member 20 makes the display unit 1 compact in size.

It is to be noted that the support member 20 is provided over an entire surface at the back side of the display member 10 in this embodiment, although this may be not necessarily provided over an entire surface as long as the flatness of the display surface is ensured. More specifically, for example, the support member 20 may be formed in a frame style at a peripheral section of the display region 10A or only at the display region 10A. However, as described in this embodiment, provision of the support member 20 over an entire surface at the back side of the display member 10 is the most reliable method that allows to ensure the flatness of the display surface for enhancing the visibility. Hereupon, “entire surface” means a state where most of a total area of the display unit 1 is covered in planar viewing of the display unit 1.

The optical film 30 prevents outside light from casting a glare on the display region 10A for example, thereby improving the visibility, and more specifically has an antireflection functionality or an antidazzle functionality. For example, when the optical film 30 has the antireflection functionality, the optical film 30 is a laminated body of a plurality of thin films with different refractive indexes that attenuates reflected light by utilizing an interference of the reflected light arising at interfaces among those thin films. Alternatively, for example, when the optical film 30 has the antidazzle functionality, an uneven surface is formed with a coating material on the top face of the optical film 30, and outside light is reflected diffusely on this uneven surface. It is to be noted that a film for protecting a display surface such as a hard coating face against any physical stimulus (external force) as a top face film may be formed instead of the optical film 30. In the display unit 1 according to this embodiment, an image is displayed at this optical film 30 side.

### [1-2. Functionality of Display Unit]

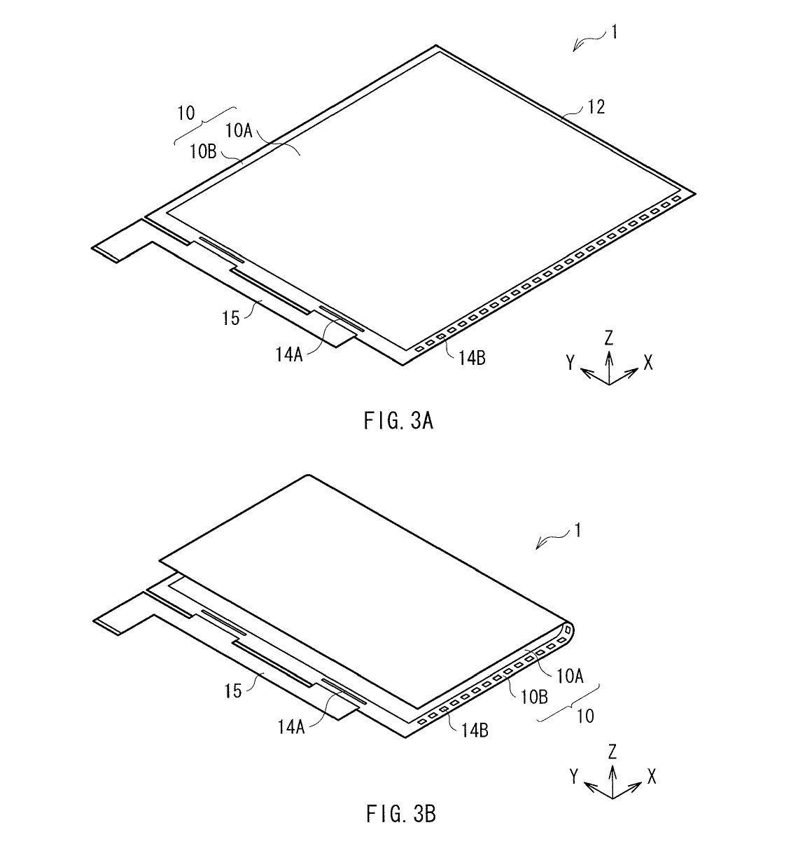

As described above, the display unit 1 is applicable to an electronic book and the like that have the flexibility. Therefore, as a matter of course, the display unit 1 is usable on a plane surface at a browsing time as shown in FIG. 3A. In addition, at a moving-around time, by taking advantage of a feature as a flexible display, the display unit 1 is usable as a portable unit in a manner of being bent or rolled as shown in an example in FIG. 3B.

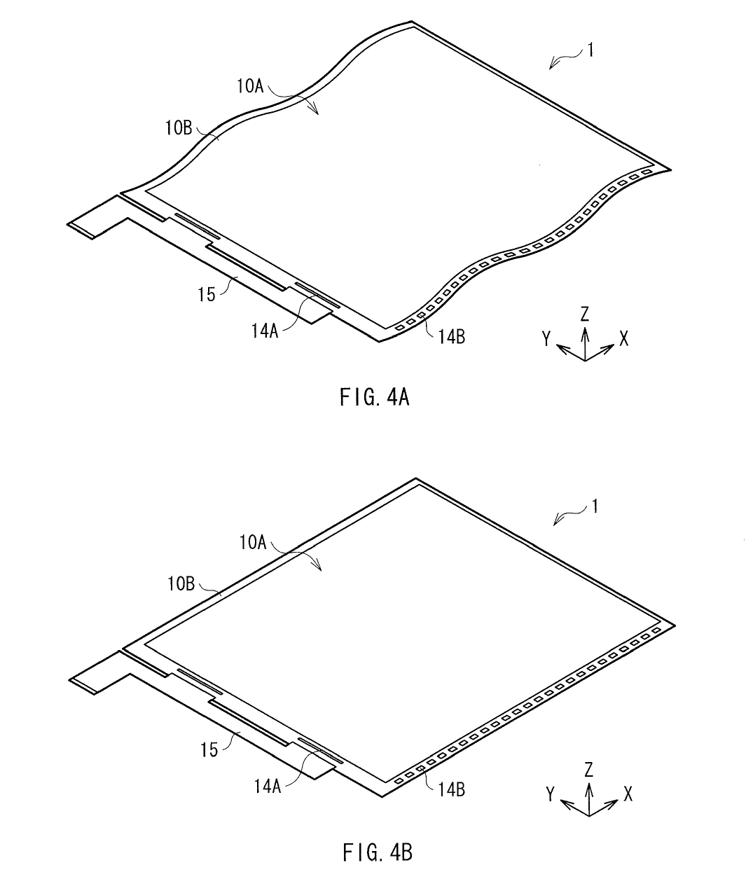

As described above, a display unit having a laminated structure with a flexible panel (equivalent to the display member 10) interposed between films makes the best possible use of the flexibility. However, as shown in FIG. 4A, a display region after bending is placed in a state where the flatness is degraded to be partially warped or uneven on the top surface. Consequently, a lack in image display uniformity that is caused by outside light reflection or the like becomes prominent at a browsing time, resulting in any position with significantly reduced visibility being found.

On the contrary, in the display unit 1 according to this embodiment, the support member 20 having a shape-memory functionality is arranged at the back side of the display member 10 having the flexibility. In the display unit 1, as with the display unit having a laminated structure as described above, as shown in FIG. 4A, the display region after bending is placed in a state where the flatness is degraded to be partially warped or uneven on the top surface. However, through an electric conduction of the display unit 1 at a browsing time, as described above, the support member 20 is heated by utilizing exhaust heat from display devices, the TFT, and the driver ICs 14A and 14B, for example. This restores a shape of the support member 20, while restoring a shape of the display member 10 that is arranged at the support member 20. In other words, as shown in FIG. 4B, any warpage or unevenness that is formed at the display region 10A is eliminated to restore the flatness of the display region 10A. This enhances the visibility of the display unit 1 at a browsing time.

As described above, in the display unit 1 according to this embodiment, the support member 20 having a shape-memory functionality is provided at the back side of the display member 10. This makes it possible to eliminate any warpage or unevenness arising at the display region 10A after bending and to achieve the flatness by utilizing exhaust heat from display devices, the TFT, the driver ICs 14A and 14B, and the like that generate heat through an electric conduction at a browsing time. As a result, this allows the visibility of the display region 10A at a browsing time to be improved without deteriorating the flexibility of the display unit 1.

### 2. Application Example

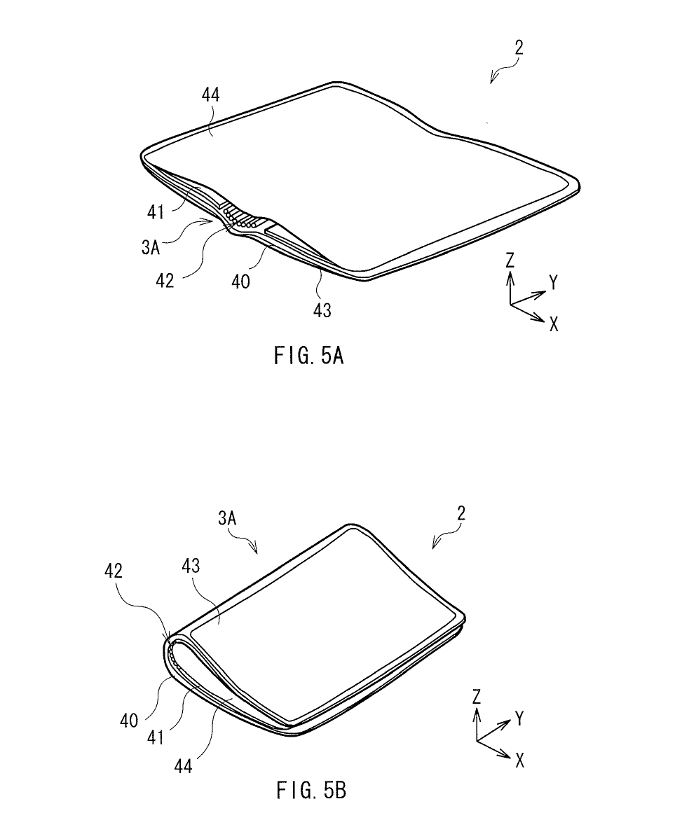

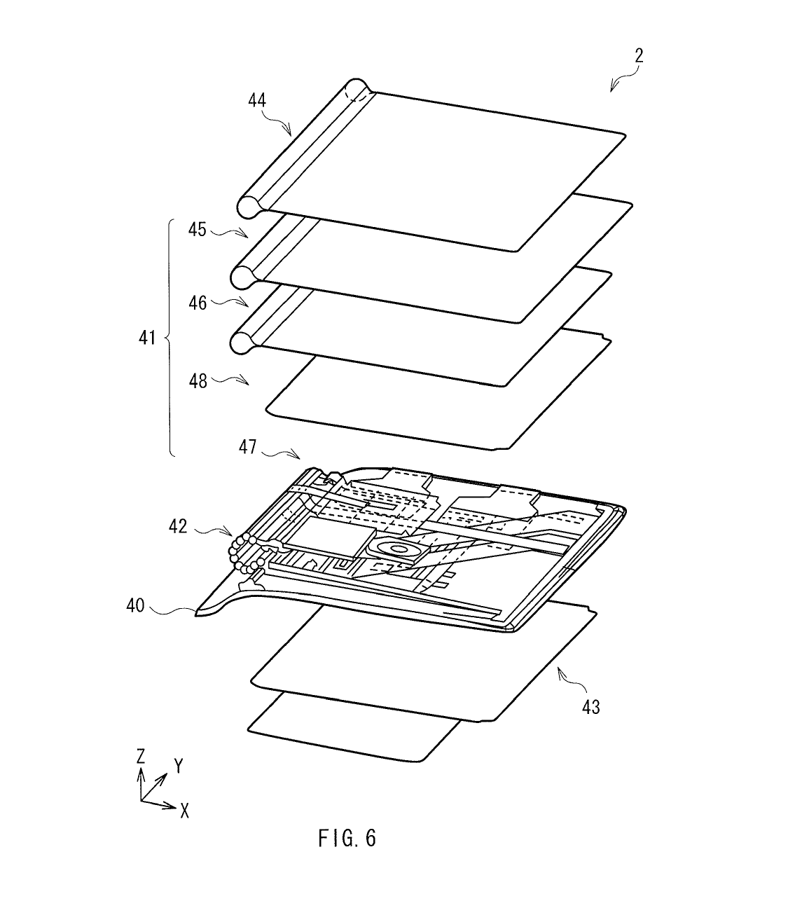

The display unit 1 according to the above-described embodiment is applicable to an electronic apparatus to be hereinafter described. Each of FIGS. 5A and 5B schematically shows a perspective configuration of an electronic apparatus (electronic book 2) according to an application example of the present disclosure. FIG. 6 is an exploded perspective diagram showing a part of one side on the electronic book 2.

The electronic book 2 is a low-profile flexible display that is formed by incorporating floppy materials as components. In this electronic book 2, it is possible to close (fold back) or open the entire unit just like a real book that is made by binding a plurality of sheets of paper (pages). A user is able to browse contents (for example, book pages) that are displayed on the electronic book 2 as if the user would read a book actually.

The electronic book 2 is provided with a laminated body 41 including a display member 45 on a support substrate 40, and has a hinge section 42 at a “backstrap” section (backstrap 3A) of the book. At the bottom face side (outward face when the book is closed) of the electronic book 2, there is provided a cover 43, while the top face side thereof (inward face when the book is closed) is covered with a protective sheet 44.

The support substrate 40 supports the laminated body 41 as a base material of the electronic book 2, and has the flexibility. The support member 20 on the display unit 1 according to the above-described embodiment is applicable to this support substrate 40.

As shown in an example in FIG. 6, the laminated body 41 has a configuration in which a system board layer 47, a circuit section 48, a detecting section 46, and the display member 45 are laminated in this order from the support substrate 40 side. All of these sections are composed of floppy materials, ensuring the flexibility in a laminated state. It is to be noted that, in this embodiment, an example where the laminated bodies 41 are provided at both of two right and left sides with the electronic book 2 open is shown, although the laminated body 41 may be alternatively provided only at one of the right and left sides.

The hinge section 42 is provided at a section corresponding to the backstrap 3A on the support substrate 40, and it is preferable that the hinge section 42 be, for example, a curvature-control hinge capable of keeping a constant curvature irrespective of any bending angle of the support substrate 40 (or electronic book 2).

The cover 43 is an exterior member for the electronic book 2, and is composed of a floppy resin film.

The protective sheet 44 protects the display member 45, while forming a display surface of the electronic book 2. This protective sheet 44 is so attached to the support substrate 40 as to cover a whole area thereof, and is composed of a soft resin film having the transparency to display light.

The display member 45 is composed of, for example, the display member 10 according to the above-described embodiment.

The detecting section 46 detects any operation of bending, depressing, and the like to be performed by a user (operation to be mainly performed along Z-direction), and more specifically this is composed of a bending sensor 46B. Examples of the bending sensor 46B include an acceleration sensor, a force sensor, a pressure sensor, a strain sensor, and a gyro sensor.

In addition to the bending sensor 46B, the detecting section 46 also has a position sensor 46A that allows to detect a touch input by a user (input using fingers, hands, a stylus, and the like). The position sensor 46A detects a user's touch position as two-dimensional position coordinates in X-direction and Y-direction. Examples of the position sensor 46A include a pressure-sensitive sensor, a two-dimensional tracking sensor, a two-dimensional touch sensor, a mesh sensor, and a capacitance-type sensor. However, it is preferable that the position sensor 46A be provided at an upper layer on the display member 45 for example. Sensing in X, Y, and Z triaxial directions by the use of the position sensor 46A and the bending sensor 46B allows to detect a position of bending operation performed by a user, a bending state, and the like. It is to be noted that a configuration of the detecting section 46 is not limited to a combination of the position sensor 46A and the bending sensor 46B, but an arbitrary triaxial sensor may be used alternatively.

On the system board layer 47, for example, there are arranged a system board on which electronic components are mounted, a hard disk drive (HDD), a cooling fan, and the like. On the system board, for example, there are mounted electronic components, such as a CPU, a main memory, a chipset, control circuits for various driving. The hard disk drive, which is connected with a connector terminal on the system board, has a built-in hard disk internally, and reads/writes information from/to this hard disk. The cooling fan cools the CPU and any other heating devices that are mounted on the system board.

The circuit section 48 is a circuit section including a TFT for driving each of the display member 45 and the detecting section 46. As such a TFT, for example, an organic TFT is used.

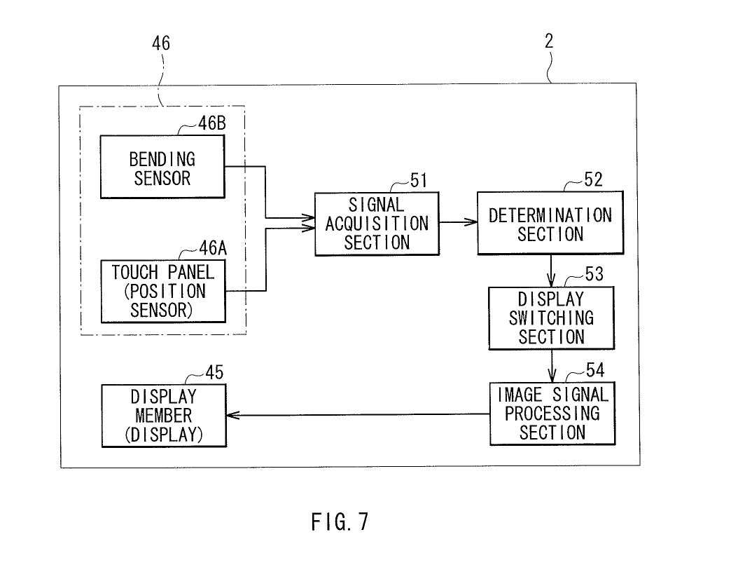

FIG. 7 shows a functional configuration of the electronic book 2. The electronic book 2 has a signal acquisition section 51, a determination section 52, a display switching section 53, and an image signal processing section 54. The signal acquisition section 51 is connected with the position sensor 46A and the bending sensor 46B that are incorporated as components.

The signal acquisition section 51 acquires a signal representing two-dimensional position information that is detected by the position sensor 46A. Further, the signal acquisition section 51 also acquires a signal representing bending information (Z-direction) that is detected by the bending sensor 46B.

The determination section 52 determines whether the electronic book 2 is bent at a local section thereof based on a detection result from each sensor.

The display switching section 53 switches display contents on the display member 45 based on a detection result from each sensor. In concrete terms, when the determination section 52 determines that a certain region on the electronic book 2 is bent, the display switching section 53 attempts to display images representing page feeding (page turning), scroll, and the like on the display member 45.

The image signal processing section 54 generates images (image signals) to be displayed on the display member 45. For example, the electronic book 2 displays a page desirable for contents downloaded via a network on the display member 45.

It is to be noted that each functionality of the signal acquisition section 51, the determination section 52, the display switching section 53, and the image signal processing section 54 is achieved by a dedicated control device or a processor (CPU) (not shown in the figure) that executes programs. Programs and data representing procedures to be executed by the processor are stored on hardware resources including storage devices, such as Random Access Memory (RAM), Read Only Memory (ROM), and Hard Disk Drive (HDD).

In this electronic book 2, the support substrate 40, the laminated body 41, the cover 43, and the protective sheet 44 are composed of floppy materials (having the flexibility), and the hinge section 42 is provided at the backstrap 3A. This allows a user to open/close the electronic book 2 in the same manner as with a case of treating a real paper book. For example, in a state where the electronic book 2 is open as illustrated in FIG. 5A, when an image (for example, image representing a first page of a book) is displayed on the display member 45, a user is able to read the page while holding the electronic book 2 with both hands or in one hand, or with electronic book 2 open (laid) on a table and the like.

As described above, in a state where certain contents are displayed on the display member 45, when a user performs a predetermined operation involving any change in a physical shape of the electronic book 2, such an operation is detected by the detecting section 46, and in turn the display switching section 53 switches display contents. In concrete terms, when the detecting section 46 detects any local warpage (bending (including twisting, depressing, and the like)) on the support substrate 40 (electronic book 2), the display switching section 53 switches display contents to display contents representing, for example, a page-feeding operation or a scroll operation. In other words, the display switching section 53 senses an input operation performed by a user (for example, page-feeding operation or scroll operation) to display contents accordingly (for example, display of any other page or line).

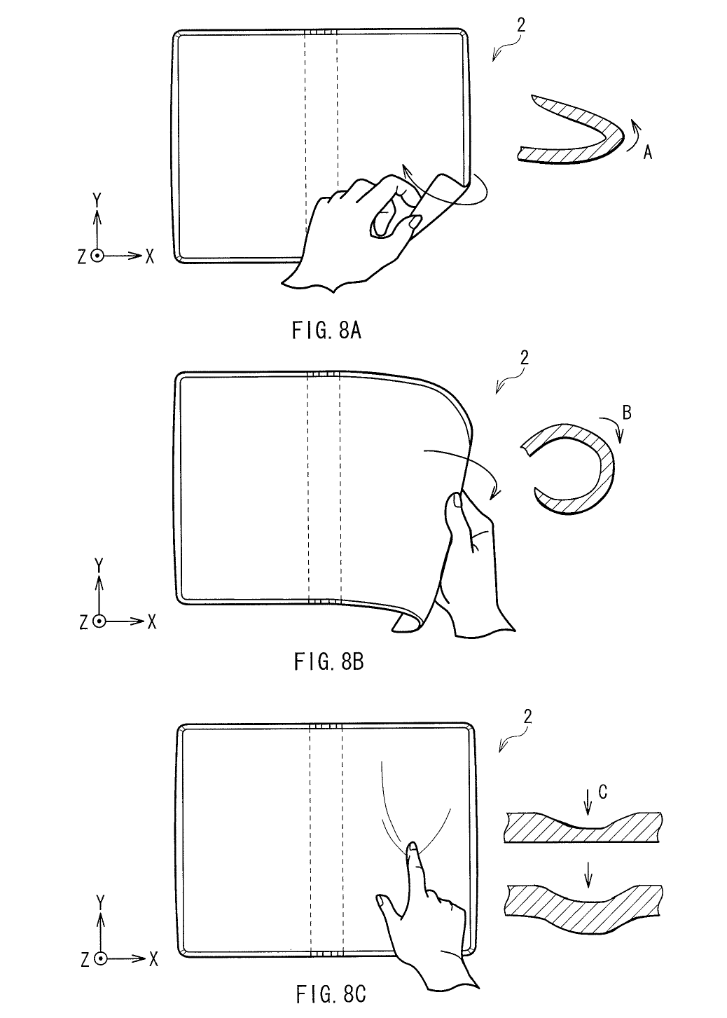

In concrete terms, the signal acquisition section 51 acquires X-Y position coordinates information from the position sensor 46A, while acquiring a displacement in Z-direction as bending (warpage) information from the bending sensor 46B to output such information to the determination section 52. The determination section 52 identifies a position (contact position of fingers and the like) within X-Y plane where a user input operation is performed based on the acquired X-Y position coordinates information, while determining whether or not the electronic book 2 is bent by a user based on the acquired bending information. It is to be noted that this determination is carried out by comparison with, for example, a threshold of the amount of bending that is held previously, and, for example, the determination section 52 determines that “the electronic book 2 is not bent” if the amount of bending according to the acquired bending information is below the threshold, and determines that “the electronic book 2 is bent” if the amount of bending is equal to or larger than the threshold. This makes it possible to sense user input operations as illustrated in examples in FIGS. 8A to 8C.

In other words, as shown in FIG. 8A, it is possible to sense an operation A to bend forward an end region of the electronic book 2, such as a corner section thereof. Further, it is possible to sense an operation B to twist and bend an end of the electronic book 2 toward the innermost part as shown in FIG. 8B, as well as an operation C to move while pushing an end of the electronic book 2 (depressing operation) as shown in FIG. 8C. Among these operations, the operations as illustrated in examples in FIGS. 8A and 8B are common actions to be made in feeding (turning) pages. On the other hand, the operation as illustrated in FIG. 8C is one of actions that a user commonly performs at a scrolling time. It is to be noted that a scroll operation involves a movement within X-Y plane, and thus, in determining a bending state, it is better to simultaneously determine whether or not the X-Y position coordinates are moving as well. However, these operations are illustrative only to be taken as typical examples for operations to be performed commonly by a user at the time of feeding (turning) book pages or scrolling.

Further, when a user input operation that is sensed by the detecting section 46 is a page-feeding operation as illustrated in examples in FIGS. 8A and 8B, for example, the display switching section 53 switches display contents to contents representing a previous page or a next page of a page that has been displayed up to that time. At this time, on the display member 45, a display may be carried out in such a manner that switching is instantaneously performed from a current page to its previous or next page, or alternatively a well-directed display may be performed to show how contents on a next page come out from a turned location like an actual book page-turning action. On the other hand, when a user input operation that is sensed by the detecting section 46 is a scroll operation as illustrated in an example in FIG. 8C, for example, the display switching section 53 switches display contents to contents representing a previous line or a next line of a predetermined line (or paragraph) within a page that has been displayed up to that time.

As described above, a user is able to perform an operation including a page-feeding or scroll action through an operation of bending the electronic book 2 locally. Specifically, since a user has only to perform the same operation as in the case of a book in a real space for the electronic book 2, the relevance between an input operation and display contents to be changed accordingly is high, which easily lends itself to a user intuitively.

Hitherto, the present technology is described with reference to the embodiment, although the present technology is not limited to the above-described embodiment, but different variations are available. For example, in the above-described embodiment, the description is provided on a configuration of the display unit 1 and the electronic book 2 by citing concrete examples, although it is not necessary to provide all the configuration elements, and any other configuration elements may be further provided.

Further, in the above-described application example, a case where the support substrate 40 has a planar shape of a rectangle is illustrated by an example, although a planar shape of the support substrate 40 is not limited hereto, but it is possible to take other various shapes including square or other polygons, circular form, elliptical form, and the like.

Further, in the above-described application example, a case where a region corresponding to the backstrap 3A of the electronic book 2 is formed to extend for dividing the support substrate 40 in half is explained with an example, although the backstrap 3A of the electronic book 2 is not limited hereto. For example, the backstrap 3A of the electronic book 2 may be formed to extend at a rightward or leftward region on the support substrate 40. In other words, at the time of a folding operation, a configuration in which one side of the support substrate 40 is exposed from the other side may be permitted. Alternatively, the number of the backstrap 3A of the electronic book 2 is not limited to one, but the plurality of backstraps 3A may be used.

Moreover, this is not shown in the figure, although a configuration that allows any other apparatus such as a keyboard to be connected with a folding-type or a tablet-type display unit or electronic apparatus may be permitted.

Additionally, in the above-described embodiment and the like, the electronic book is taken as an example of the display unit or the electronic apparatus according to the above-described respective embodiments of the present disclosure, although the display unit or the electronic apparatus according to the above-described respective embodiments of the present disclosure may be used for electronic apparatuses such as various mobile apparatuses (notebook Personal Computer (PC), portable audio player, cellular phone, Personal Digital Assistant (PDA)). Further, the display unit or the electronic apparatus may be used not only as a book reader, but also for the length and breadth of display units and electronic apparatuses that allow music player, video payer, photograph viewer, map application, web browser, and the like to be browsed.

It is to be noted that the technology may be configured as follows.

(1) A display unit, including:

a display member having flexibility; and

a support member disposed at a back side of the display member and having a shape-memory functionality.

(2) The display unit according to (1), wherein the support member is provided over a whole area at the back side of the display member.

(3) The display unit according to (1) or (2), wherein the support member memorizes a shape that keeps flatness at the time of heating.

(4) The display unit according to any one of (1) to (3), wherein the support member is composed of sheet-like shape-memory alloy.

(5) The display unit according to any one of (1) to (4), further including a source supplying heat to the support member.

(6) The display unit according to any one of (1) to (5), wherein the heat source is a display device composing the display member.

(7) The display unit according to any one of (1) to (5), wherein the heat source is a driving device composing the display member.

(8) The display unit according to any one of (1) to (7), wherein a shape-memory functionality of the support member functions by heating at temperature of approximately 40 degrees centigrade or less.

(9) An electronic apparatus with a display unit, the display unit including:

a display member having flexibility; and

a support member disposed at a back side of the display member and having a shape-memory functionality.

The present disclosure contains subject matter related to that disclosed in Japanese Priority Patent Application JP 2012-080641 filed in the Japan Patent Office on Mar. 30, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display unit, comprising:
a display member having flexibility; and
a support member disposed at a back side of the display member and having a shape-memory functionality.

2. The display unit according to claim 1, wherein the support member is provided over a whole area at the back side of the display member.

3. The display unit according to claim 1, wherein the support member memorizes a shape that keeps flatness at the time of heating.

4. The display unit according to claim 1, wherein the support member is composed of sheet-like shape-memory alloy.

5. The display unit according to claim 1, further comprising a source supplying heat to the support member.

6. The display unit according to claim 5, wherein the heat source is a display device composing the display member.

7. The display unit according to claim 5, wherein the heat source is a driving device composing the display member.

8. The display unit according to claim 1, wherein a shape-memory functionality of the support member functions by heating at temperature of approximately 40 degrees centigrade or less.

9. An electronic apparatus with a display unit, the display unit comprising:
a display member having flexibility; and
a support member disposed at a back side of the display member and having a shape-memory functionality.
